(19) United States
(12) Patent Application Publication
(10) Pub. No.: US 2026/0030153 A1
(43) Pub. Date: Jan. 29, 2026

(54) REPORTING FOR HOST INITIATED INTERNAL MAINTENANCE OPERATIONS

(71) Applicant: Micron Technology, Inc., Boise, ID (US)

(72) Inventor: David Aaron PALMER, Boise, ID (US)

(21) Appl. No.: 19/219,309

(22) Filed: May 27, 2025

Related U.S. Application Data
(60) Provisional application No. 63/675,449, filed on Jul. 25, 2024.

(51) Int. Cl. G06F 12/02; G11C 29/52

(52) U.S. Cl. CPC G06F 12/0246; G11C 29/52; G06F 2212/7205

(57) ABSTRACT

In some implementations, a memory apparatus may transmit, to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus. The memory apparatus may receive, from the host system, scheduling information for one or more internal maintenance operations, wherein the scheduling information is based on the amount of internal maintenance operation work. The memory apparatus may perform the one or more internal maintenance operations in accordance with the scheduling information.

### CROSS-REFERENCE TO RELATED APPLICATION

This Patent Application claims priority to U.S. Provisional Patent Application No. 63/675,449, filed on Jul. 25, 2024, entitled “REPORTING FOR HOST INITIATED INTERNAL MAINTENANCE OPERATIONS,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to reporting for host initiated internal maintenance operations.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

A non-volatile memory device, such as a NAND memory device, may use circuitry to enable electrically programming, erasing, and storing of data even when a power source is not supplied. Non-volatile memory devices may be used in various types of electronic devices, such as computers, mobile phones, or automobile computing systems, among other examples. A non-volatile memory device may include an array of memory cells, a page buffer, and a column decoder. In addition, the non-volatile memory device may include a control logic unit (e.g., a controller), a row decoder, or an address buffer, among other examples. The memory cell array may include memory cell strings connected to bit lines, which are extended in a column direction.

A memory cell, which may be referred to as a “cell” or a “data cell,” of a non-volatile memory device may include a current path formed between a source and a drain on a semiconductor substrate. The memory cell may further include a floating gate and a control gate formed between insulating layers on the semiconductor substrate. A programming operation (sometimes called a write operation) of the memory cell is generally accomplished by grounding the source and the drain areas of the memory cell and the semiconductor substrate of a bulk area, and applying a high positive voltage, which may be referred to as a “program voltage,” a “programming power voltage,” or “VPP,” to a control gate to generate Fowler-Nordheim tunneling (referred to as “F-N tunneling”) between a floating gate and the semiconductor substrate. When F-N tunneling is occurring, electrons of the bulk area are accumulated on the floating gate by an electric field of VPP applied to the control gate to increase a threshold voltage of the memory cell.

### BRIEF DESCRIPTION OF THE DRAWINGS

FIG. 1 is a diagram illustrating an example system capable of reporting for host initiated internal maintenance operations.

FIG. 2 is a diagram illustrating an example of a garbage collection operation.

FIGS. 3A-3C are diagrams of an example of reporting for host initiated internal maintenance operations.

FIG. 4 is a flowchart of an example method associated with reporting for host initiated internal maintenance operations.

FIG. 5 is a flowchart of an example method associated with reporting for host initiated internal maintenance operations.

FIG. 6 is a flowchart of an example method associated with reporting for host initiated internal maintenance operations.

### DETAILED DESCRIPTION

In some examples, a memory apparatus (e.g., a non-volatile memory device, a NAND device, a flash device, and/or a universal flash storage (UFS) device) may perform one or more internal maintenance operations. For example, the memory apparatus may perform one or more internal maintenance operations to consolidate free space as data is continuously overwritten and previous versions of data become obsolete. As used herein, “internal maintenance” operation may refer to an operation performed by the memory apparatus associated with the management, optimization, and/or integrity of data stored by the memory device. In some examples, an internal maintenance operation may be an operation performed by the memory apparatus for data stored by the memory apparatus (e.g., to manage the data stored by the memory apparatus). For example, an internal maintenance operation may be different than an operation to access memory resources of the memory apparatus, such as a read operation or a write operation. As an example, an internal maintenance operation may include a refresh operation, a defragmentation operation, a folding operation, a garbage collection operation, a wear leveling operation, a purge operation, a bad block management operation, an error correction operation, and/or a read disturb management operation, among other examples.

The actual requirements for internal maintenance are best known internally by the memory apparatus because the memory apparatus may keep track of invalidated data blocks and areas where consolidation can occur. However, the optimal timing for performing the internal maintenance operations may be difficult for the memory apparatus to determine. For example, the optimal timing may be based on operations of a host system. For example, the host system may be configured to determine when it would be least disruptive to system performance for the memory apparatus to perform internal maintenance operations.

Therefore, in some examples, the host system may initiate one or more internal maintenance operations to be performed by the memory apparatus, such as a host-initiated defragmentation (HID), among other examples. For example, the host system may initiate the one or more internal maintenance operations at a time at which the host system has determined that the performance of the one or more internal maintenance operations will be least disruptive to system performance. However, the host system may be unaware of, or have an inaccurate estimation of, the amount of work to be performed by the memory apparatus for the one or more internal maintenance operations. Therefore, in some examples, the host system may cause the memory apparatus to perform internal maintenance operations more frequently than is necessary (e.g., based on the actual requirements for internal maintenance of the memory apparatus). Excessive triggering of internal maintenance operations by the host system may result in premature wear-out of the memory apparatus because each memory cell included in the memory apparatus may have a limited number of write-erase cycles (e.g., program-erase cycles) before that memory cell degrades and/or can no longer be used to store data. In some other examples, the host system may cause the memory apparatus to perform internal maintenance operations less frequently than is necessary (e.g., based on the actual requirements for internal maintenance of the memory apparatus). This may result in degraded performance of the memory apparatus because the memory apparatus is unable to perform the internal maintenance needed to maintain, optimize, and/or improve performance of the memory apparatus.

Some implementations described herein enable reporting for host initiated internal maintenance operations. For example, a host system and a memory apparatus may communicate to enable intelligent management of internal maintenance operations in a memory apparatus. This may enable optimized performance and lifespan utilization of the memory apparatus while also reducing conflicts with host operations. For example, the memory apparatus may transmit, and the host system may receive, an indication of the amount of internal maintenance work that is to be completed by the memory apparatus. The host system may transmit, and the memory apparatus may receive, scheduling information for one or more internal maintenance operations, where the scheduling information is based on the reported amount of internal maintenance work. The memory apparatus may perform one or more internal maintenance operations in accordance with the scheduling information (e.g., at a time and/or for an amount of time indicated by the scheduling information).

In some aspects, the amount of internal maintenance work may be based on one or more parameters. The one or more parameters may include one or more lifespan utilization parameters (e.g., indicating an actual resource utilization of the memory apparatus compared to an estimated lifespan of the memory apparatus), and/or one or more types of additional maintenance operations to be performed by the memory apparatus, among other examples.

In some aspects, the amount of internal maintenance work may be an adjusted amount of work for internal maintenance operations of the memory apparatus. For example, the memory apparatus may determine an amount of work based on a size of internal maintenance operations to be performed by the memory apparatus. The memory apparatus may adjust (e.g., modify, increase, or decrease) the amount of work based on the one or more parameters.

As a result, the host system may initiate internal maintenance operations for the memory apparatus at a time that reduces the impact to system performance (e.g., as determined by the host system) and for a duration and/or frequency that is optimized based on the usage patterns and predicted lifespan of the memory apparatus (e.g., as indicated by the reported amount of work). For example, the reporting of the amount of work by the memory apparatus (e.g., that is adjusted by the memory apparatus) may reduce the likelihood of excessive degradation of memory cells of the memory apparatus that may otherwise be caused by over-utilization of host-initiated internal maintenance operations. Additionally, the reporting of the amount of work by the memory apparatus (e.g., that is adjusted by the memory apparatus) may improve the performance of the memory apparatus by improving the likelihood that the memory apparatus has sufficient time to perform the amount of work that is associated with performance-enhancing internal maintenance operations. For example, the memory apparatus reporting the amount of work may improve the likelihood that internal maintenance operations are performed in a manner that aligns with the usage patterns and predicted lifespan of the memory apparatus, thereby preventing unnecessary wear cycles and improving the lifespan of the memory apparatus. Moreover, by enabling the host system to schedule internal maintenance operations, the memory apparatus may operate more efficiently in the overall system because the host system scheduling may minimize operational interference and/or may enable more predictable performance.

Further, by performing internal maintenance operations during periods scheduled or indicated by the host system, the memory apparatus can engage in additional tasks (e.g., data segregation and alignment, hot and cold data sorting, static wear leveling, table garbage collection, and/or other performance-based maintenance operations) without vying for processing resources during peak operational periods of the host system. For example, if the memory apparatus has one or more performance-based maintenance operations to perform, then the memory apparatus may report an amount of work that is greater than the amount of work that is based on the size of internal maintenance operations to be performed by the memory apparatus. This may enable the host system to schedule or allocate additional time and/or resources for the memory apparatus to perform the additional tasks. This coordinated scheduling facilitates maintenance tasks that are associated with maintaining performance and extending the effective lifespan of the memory apparatus.

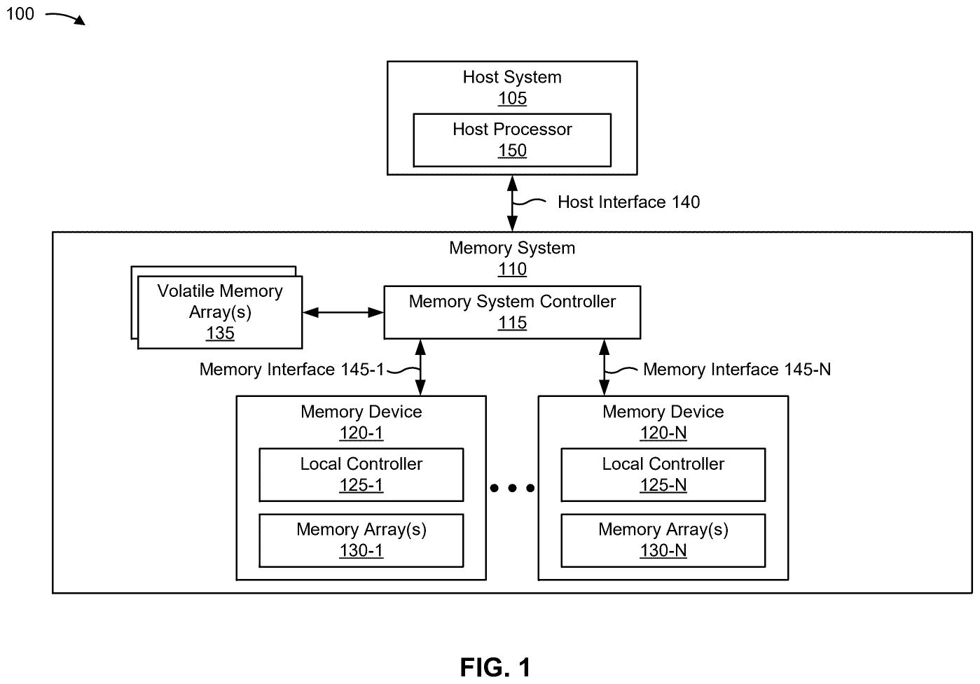

FIG. 1 is a diagram illustrating an example system 100 capable of reporting for host initiated internal maintenance operations. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions.

Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some examples, one or more controllers (e.g., the memory system controller 115, a local controller 125, or an external controller) may cause a memory device 120 to perform one or more internal maintenance operations. The one or more internal maintenance operations may include a refresh operation, a defragmentation operation, a folding operation, a garbage collection operation, a wear leveling operation, a purge operation, a bad block management operation, an error correction operation, and/or a read disturb management operation, among other examples. In some examples, as described in more detail elsewhere herein, the one or more controllers (e.g., the memory system controller 115, a local controller 125, or an external controller) may transmit or provide, and the host system 105 (e.g., the host processor 150) may receive or obtain, an indication of an amount of internal maintenance operation work to be completed for one or more memory devices 120. The host system 105 (e.g., the host processor 150) may transmit or provide, and the one or more controllers (e.g., the memory system controller 115, a local controller 125, or an external controller) may receive or obtain, scheduling information for one or more internal maintenance operations (e.g., the scheduling information being based on the amount of internal maintenance operation work reported to the host system 105). The scheduling information may initiate, trigger, and/or otherwise schedule the memory system 110 and/or one or more memory devices 120 to perform internal maintenance operations. For example, the one or more controllers (e.g., the memory system controller 115, a local controller 125, or an external controller) may perform one or more internal maintenance operations (e.g., for one or more memory devices 120) in accordance with the scheduling information (e.g., at a time and/or for a duration indicated by the scheduling information).

In some implementations, one or more systems, devices, apparatuses, components, and/or controllers of FIG. 1 may be configured to transmit, to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus; receive, from the host system, scheduling information for one or more internal maintenance operations, wherein the scheduling information is based on the amount of internal maintenance operation work; and perform, in accordance with the scheduling information, the one or more internal maintenance operations.

In some implementations, one or more systems, devices, apparatuses, components, and/or controllers of FIG. 1 may be configured to receive, from a memory apparatus, an indication of an amount of internal maintenance operation work to be completed by the memory apparatus; and transmit, to the memory apparatus, scheduling information for internal maintenance operations, wherein the scheduling information indicates an amount of time during which the memory apparatus can perform the internal maintenance operations, and wherein the scheduling information is based on the amount of internal maintenance operation work.

In some implementations, one or more systems, devices, apparatuses, components, and/or controllers of FIG. 1 may be configured to transmit, to a host system, an indication of an adjusted amount of work for internal maintenance operations to be completed for the memory apparatus, wherein the adjusted amount of work is adjusted from a size of the internal maintenance operations; receive, from the host system, scheduling information for the internal maintenance operations, wherein the scheduling information is based on the adjusted amount of work; and perform, in accordance with the scheduling information, one or more internal maintenance operations.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

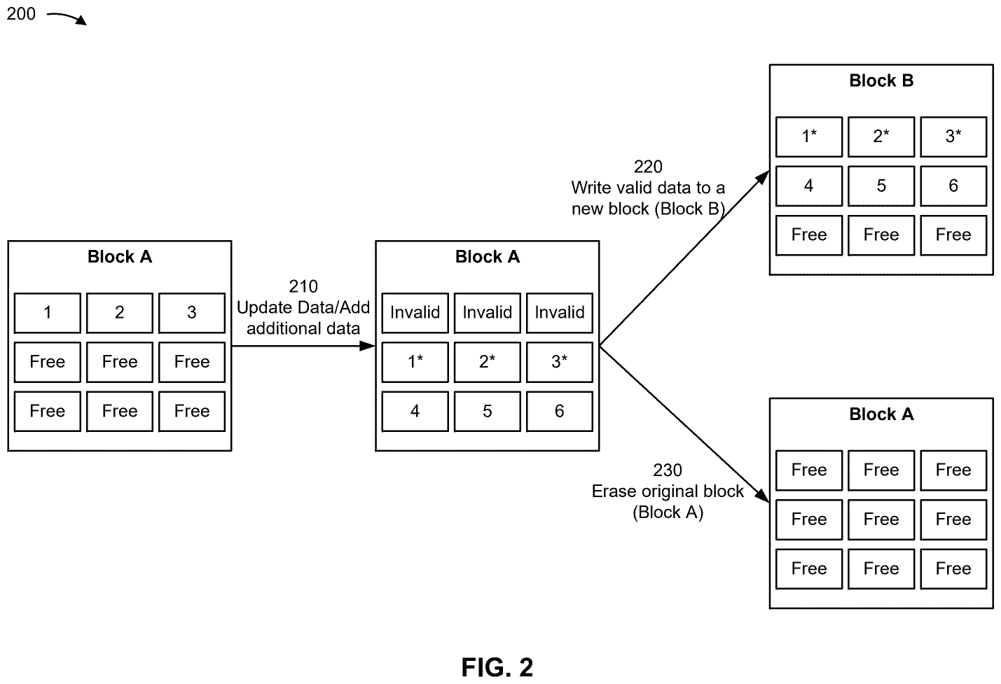

FIG. 2 is a diagram illustrating an example 200 of a garbage collection operation. Garbage collection is an example of an internal maintenance operation described herein. Garbage collection may be a function or operation of a memory apparatus (e.g., the memory system 110 and/or a memory device 120) associated with reclaiming memory that is no longer in use. For example, the memory apparatus (e.g., one or more controllers, such as the memory system controller 115, a local controller 125, or an external controller) may perform one or more operations described herein to reclaim memory which was previously allocated by the memory apparatus, but is no longer referenced or valid.

For example, as shown in FIG. 2, a block (e.g., block A) may be associated with a set of pages. As shown, one or more pages of the block A may be associated with valid data (e.g., shown as page 1, page 2, and page 3). Other pages of the block A may not have data written to them and/or may be free (e.g., shown as “free” in FIG. 2). In a first operation 210, the memory device may update data (e.g., re-write data) that is stored by the block A and/or may write new (or additional) data to the block A. For example, the memory apparatus may re-write the data stored in page 1, page 2, and page 3 to different pages of the Block A (e.g., shown as page 1*, page 2*, and page 3* in FIG. 2). The memory apparatus may mark the pages that previously stored the now re-written data as invalid. For example, erase operations may be performed at the block level (e.g., individual pages may not be erased), therefore, when data is re-written or updated, the pages that store the now stale data may be marked as invalid by the memory apparatus. Additionally, the memory apparatus may receive additional data (e.g., from the host system 105) to be written. The memory apparatus may write the additional data to other pages of the block A (e.g., shown as page 4, page 5, and page 6).

As shown in FIG. 2, after the re-writing of previously stored data and/or the writing of additional data to the block A, all pages of the block A may store data (e.g., the block A may be full). However, some pages of the block A may store stale or invalid data. Therefore, the memory apparatus may perform a garbage collection operation to reclaim memory which is allocated to stale or invalid data and to preserve the valid data stored by the block A. In some implementations, a given block may be associated with a valid page count or a valid TU count indicating a quantity of pages of the given block that store valid data. In some implementations, the memory apparatus may select a block (e.g., the block A) to be associated with the garbage collection operation based on the valid page count or the valid TU count of the block satisfying a threshold. As another example, the memory apparatus may select a block (e.g., the block A) to be associated with the garbage collection operation based on the block being associated with the most invalid pages or the lowest valid page count or valid TU count among a set of blocks.

In a second operation 220, the memory apparatus may write valid data stored in the block A to a different block (e.g., block B). For example, as shown in FIG. 2, the data stored by the page 1*, page 2*, and page 3*, page 4, page 5, and page 6 of the block A may be written to, or folded to, respective pages of the block B (e.g., this may referred to as a garbage collection write operation or a folding write operation). In such examples, the block A may be referred to as a victim block for the garbage collection operation. The memory apparatus may update an address (e.g., a logical block address (LBA)) of the data that is written to the block B (e.g., indicating an updated physical location where the data is stored).

In a third operation 230, the memory apparatus may perform an erase operation to erase data stored by the block A (e.g., after writing or folding the valid data to the block B). As a result, the block A may be erased, and all pages of the block A may be available to be written. This may enable the memory device to reclaim memory that was previously used to store stale or invalid data and to preserve valid data stored by the memory apparatus. This may improve a performance of the memory apparatus and/or may increase a lifespan of the memory apparatus. The memory apparatus may perform other internal maintenance operations to improve the performance of the memory apparatus and/or increase the lifespan of the memory apparatus, such as a refresh operation, a defragmentation operation, a wear leveling operation, a purge operation, a bad block management operation, an error correction operation, and/or a read disturb management operation, among other examples.

As indicated above, FIG. 2 is provided as an example. Other examples may differ from what is described with regard to FIG. 2.

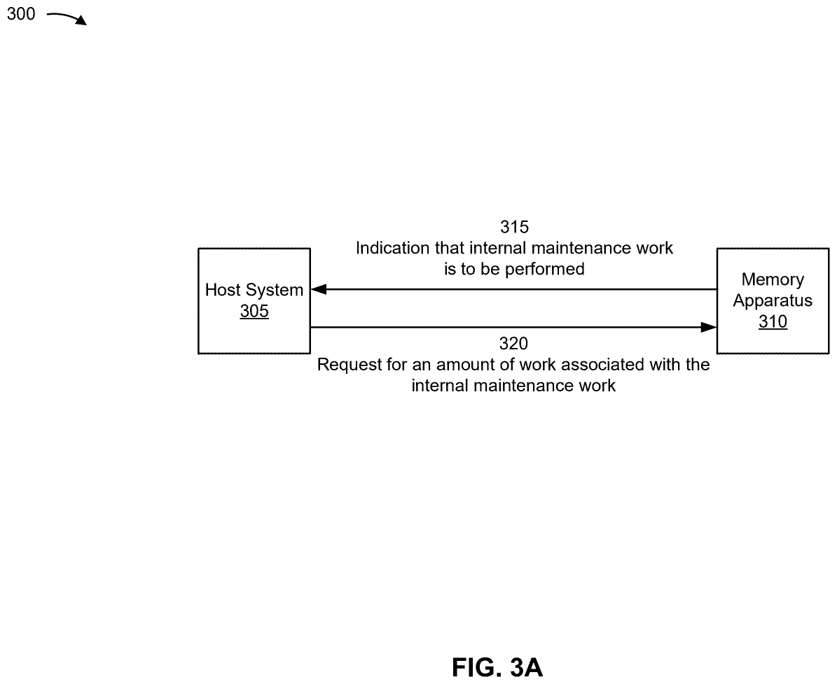

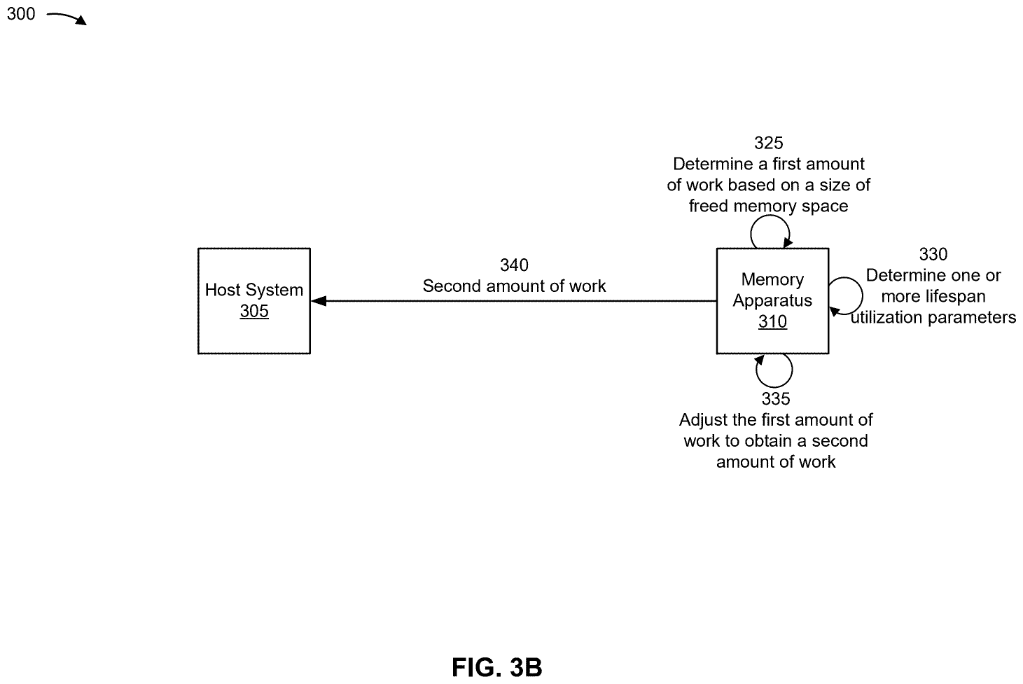

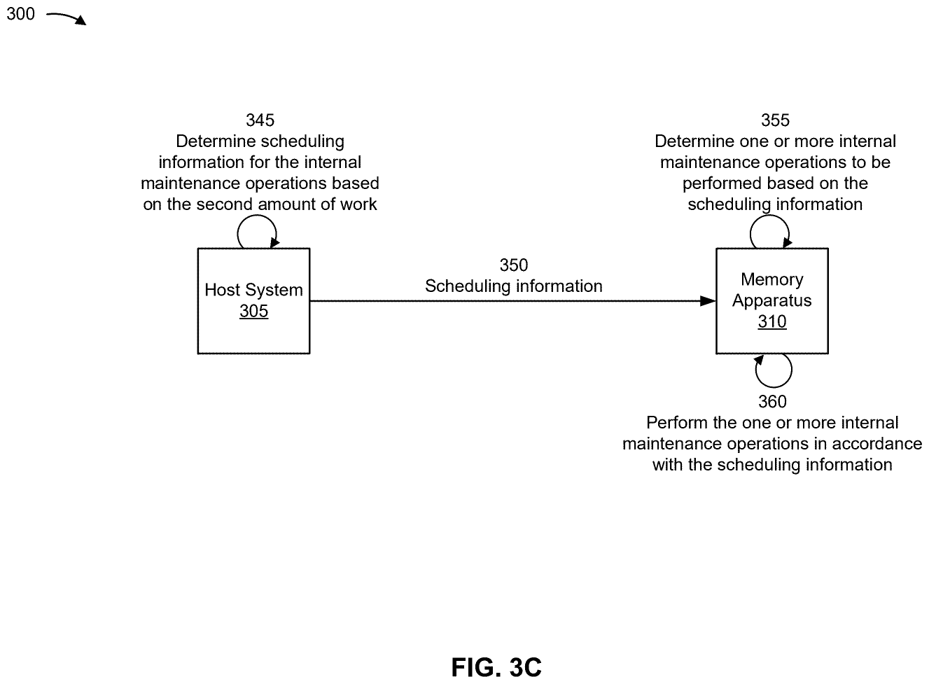

FIGS. 3A-3C are diagrams of an example 300 of reporting for host initiated internal maintenance operations. The operations described in connection with FIGS. 3A-3C may be performed by the memory system 110 and/or one or more components of the memory system 110, such as the memory system controller 115, one or more memory devices 120, and/or one or more local controllers 125. Additionally, or alternatively, the operations described in connection with FIGS. 2A-2C may be performed by the system 100, the host system 105, one or more component of the host system 105 (e.g., the host processor 150), and/or the host interface 140.

As shown in FIGS. 3A-3C, the example 300 may include a host system 305 and a memory apparatus 310. The host system 305 may be the host system 105. The memory apparatus 310 may be, or may include, the memory system 110, one or more memory devices 120, and/or one or more controllers (e.g., the memory system controller 115 and/or one or more local controllers 125).

As shown in FIG. 3A, and by reference number 315, the memory apparatus 310 may transmit, and the host system 305 may receive, an indication that the one or more internal maintenance operations are to be performed by the memory apparatus 310. For example, the memory apparatus 310 may transmit an indication that the memory apparatus 310 has internal maintenance operations or work to be completed.

For example, the memory apparatus 310 may track or monitor one or more performance parameters of the memory apparatus 310 to determine whether the one or more internal maintenance operations are to be performed by the memory apparatus 310. For example, the memory apparatus 310 may monitor free space in memory of the memory apparatus 310, track data usage patterns, and/or estimate the wear on memory cells of the memory apparatus 310, among other examples. For example, the memory apparatus may monitor the usage and availability of data blocks. If the number of free blocks does not satisfy a threshold, then the memory apparatus 310 may determine that a garbage collection operation should be performed to reclaim space in the memory.

Additionally, or alternatively, the memory apparatus 310 may perform a write amplification operation to estimate the effectiveness of a garbage collection operation. If an amplification factor satisfies a threshold, then the memory apparatus 310 may determine that a garbage collection operation should be performed to reclaim space in the memory.

As another example, the memory apparatus 310 may use a wear leveling algorithm to monitor the usage of memory cells in the memory apparatus 310. For example, as memory cells undergo a certain number of write or erase cycles, the memory cells may become susceptible to wear. The wear leveling algorithm may enable the memory apparatus to track the usage of each memory cell and to determine when to redistribute data among the memory cells to ensure that no individual cells are overly stressed (e.g., via a wear leveling operation). If a given memory cell is nearing an end of an expected lifespan, then the memory apparatus 310 may determine that a wear leveling operation is to be performed to redistribute data and extend the lifespans of the memory cells of the memory apparatus 310. The memory apparatus 310 may determine that one or more other internal maintenance operations are to be performed. For example, the memory apparatus 310 may determine that a refresh operation is to be performed (e.g., based on an amount of time elapsed from a last refresh cycle), a defragmentation operation is to be performed (e.g., based on a fragmentation level), a purge operation is to be performed (e.g., based on a security protocol or data management policy), a bad block management operation is to be performed (e.g., based on a number of identified data blocks having errors), an error correction operation is to be performed (e.g., based on detecting one or more errors), and/or a read disturb management operation is to be performed (e.g., based on a disturbance level for read operations), among other examples.

In some aspects, as shown by reference number 320, the host system 305 may transmit, and the memory apparatus 310 may receive, a request for an amount of work associated with the internal maintenance operation(s) to be performed by the memory apparatus 310. For example, the host system 305 may request the amount of work to enable the host system 305 to obtain an indication of the workload that the memory apparatus 310 will manage internally. In some aspects, the host system 305 may transmit the request for the amount of work based on receiving the indication that the one or more internal maintenance operations are to be performed by the memory apparatus 310 (e.g., as depicted and described in connection with reference number 315). For example, the host system 305 may transmit the request for the amount of work based on receiving the indication that the memory apparatus 310 is to perform one or more internal maintenance operations. Additionally, or alternatively, the host system 305 may periodically transmit requests for the amount of work.

Additionally, or alternatively, the host system 305 may transmit the request based on detecting an event. For example, the event may be indicative of an upcoming time in which the performance of internal maintenance operations by the memory apparatus is unlikely to negatively impact performance of the host system 305 and/or a system that includes the host system 305 and the memory apparatus 310 (e.g., the system 100). For example, the host system 305 may detect the event based on a level of activity of the host system 305 satisfying an idle threshold (e.g., indicating that the host system 305 is in an idle period for activity). Additionally, or alternatively, the host system 305 may detect the event based on a current time. For example, the host system 305 may analyze traffic patterns associated with the host system 305 to determine one or more time periods during which activity levels or system operations are typically low (e.g., during nighttime periods). The host system 305 may detect the event based on the current time being included in the one or more time periods. This may enable the host system 305 to obtain up-to-date information associated with the amount of work for internal maintenance operations of the memory apparatus 310 during, or close to, times during which the host system 305 expects to trigger or schedule the memory apparatus to perform the internal maintenance operations, as described in more detail elsewhere herein.

As shown in FIG. 3B, and by reference number 325, the memory apparatus 310 may determine a first amount of work based on the size of freed memory space associated with one or more internal maintenance operations. For example, the first amount of work may be associated with an amount of data that is to be reorganized, modified, or erased during the one or more internal maintenance operations. For example, the first amount of work may be a baseline measurement for internal maintenance workload (e.g., prior to considering additional factors, as described in more detail herein). The first amount of work may be based on (e.g., may be) an expected amount of space in memory that will be freed as a result of performing the one or more internal maintenance operations. The memory apparatus 310 may determine the first amount of work based on how much space needs to be reclaimed in memory, how evenly data is distributed across the memory cells, how frequently data is accessed, and/or one or more performance metrics (e.g., an error rate, a wear level, and/or a temperature), among other examples. The first amount of work may be represented by a size of data to be read and/or written as part of the performing the one or more internal maintenance operations (e.g., in megabytes). As another example, the first amount of work may be represented by an estimated amount of time for the memory apparatus 310 to perform the one or more internal maintenance operations (e.g., based on one or more performance capabilities of the memory apparatus 310).

The memory apparatus 310 may determine one or more factors or parameters associated with adjusting or modifying the first amount of work. The one or more factors or parameters may include one or more lifespan utilization parameters, and/or one or more additional operations to be performed by the memory apparatus 310 (e.g., the types of additional operations to be performed by the memory apparatus 310). For example, as shown by reference number 330, the memory apparatus 310 may determine one or more lifespan utilization parameters. A lifespan utilization parameter may be indicative of an actual memory or resource utilization of the memory apparatus 310 compared to an estimated lifespan of the memory apparatus 310. For example, the memory apparatus 310 may be associated with an estimated lifespan that indicates an estimated number of operations or cycles that memory apparatus 310 can perform before it is expected that a performance of the memory apparatus 310 is no longer satisfactory. For example, the estimated lifespan may indicate an estimated number of write-erase cycles (e.g., program-erase cycles) that the memory apparatus 310 can perform before the integrity and/or reliability of the memory cells of the memory apparatus 310 degrade (e.g., before the memory cells of the memory apparatus 310 become unusable). As another example, the estimated lifespan may be represented as a total amount of data that can be written by the memory apparatus over a lifetime of the memory apparatus (e.g., before a performance of the memory apparatus 310 is expected to degrade to an unusable level). For example, the total amount of data may be indicated by a terabytes written (TBW) metric or rating of the memory apparatus 310. The estimated lifespan may be referred to as an endurance or an endurance rating of the memory apparatus 310.

The memory apparatus 310 may determine or estimate how far (e.g., in terms of time) that the memory apparatus 310 is into the estimated lifespan of the memory apparatus 310. For example, in addition to the performance-based metrics indicative of the lifespan of the memory apparatus (e.g., the TBW metric and/or the estimated total number of program-erase cycles), the memory apparatus 310 may be associated with a time-based metric indicative of the estimated lifespan of the memory apparatus 310. For example, a capability or rating of the memory apparatus 310 may indicate that the memory apparatus is expected to be operational (e.g., before a performance of the memory apparatus 310 is expected to degrade to an unusable level) for M years.

The memory apparatus 310 may determine a performance utilization for the estimated lifespan of the memory apparatus 310 by comparing an actual performance metric of the memory apparatus to a performance metric indicating the estimated lifespan of the memory apparatus 310. For example, the memory apparatus 310 may determine a first number of program-erase cycles that have been performed in the lifetime of the memory apparatus 310 (e.g., an average number of program-erase cycles across data blocks or memory cells of the memory apparatus 310). The memory apparatus 310 may compare the first number of program-erase cycles to a second number of program-erase cycles that indicate the estimated lifespan of the memory apparatus 310 (e.g., that indicate a number of program-erase cycles that the memory apparatus 310 is estimated to be able to perform before a degradation of performance). The performance utilization may indicate a comparison or ratio between the first number of program-erase cycles and the second number of program-erase cycles. For example, the performance utilization may indicate a percentage of the second number of program-erase cycles that have been performed by the memory apparatus 310 to date (e.g., the performance utilization may indicate that the memory apparatus 310 has performed X % of the estimated number of program-erase cycles that the memory apparatus 310 can perform during the lifespan of the memory apparatus 310). As used herein, a percentage may also include, or may be, a decimal form of the percentage (e.g., 25% may include, or may be, 0.25).

As another example, the memory apparatus 310 may determine a first amount of data that has been written in the lifetime of the memory apparatus 310. The memory apparatus 310 may compare the first amount of data to a second amount of data indicated by the TBW metric or rating of the memory apparatus 310 (e.g., the second amount of data may indicate a total amount of data that the memory apparatus 310 is estimated to be able to write before a degradation of performance). The performance utilization may indicate a comparison or ratio between the first amount of data and the second amount of data. For example, the performance utilization may indicate a percentage of the second amount of data that has been written by the memory apparatus 310 to date (e.g., the performance utilization may indicate that the memory apparatus 310 has written Y % of the estimated TBW that the memory apparatus 310 can write during the lifespan of the memory apparatus 310).

The memory apparatus 310 may determine a time utilization for the estimated lifespan of the memory apparatus 310. For example, the memory apparatus 310 may determine an amount of time that the memory apparatus 310 has been operating to date.

For example, the memory apparatus 310 may estimate the amount of time that the memory apparatus 310 has been operating. The memory apparatus 310 may estimate the amount of time based on one or more internal clocks of the memory apparatus 310, a number of times that the memory apparatus 310 has been woken up and/or entered a sleep mode, and/or one or more external clocks (e.g., a real-time clock obtained via the host system 305), among other examples. For example, the host system 305 may provide, and the memory apparatus 310 may obtain, an indication of a real time and date, thereby enabling the memory apparatus to determine an amount of time that the memory apparatus 310 has been operating. The memory apparatus 310 may compare the amount of time that the memory apparatus 310 has been operating to an estimated amount of time for which the memory apparatus 310 is expected to be operational. The time utilization may be based on the comparison. For example, the time utilization may indicate a comparison or ratio between the amount of time that the memory apparatus 310 has been operating to an estimated amount of time for which the memory apparatus 310 is expected to be operational. As an example, the time utilization may be represented as a percentage of the estimated amount of time for which the memory apparatus 310 is expected to be operational that has lapsed (e.g., indicating that the memory apparatus has been operating for T % of the expected lifespan in terms of time).

The memory apparatus 310 may determine a lifespan utilization parameter based on the performance utilization and the time utilization. For example, the lifespan utilization parameter may be based on, or otherwise associated with, a comparison of the performance utilization and the time utilization. In some examples, the lifespan utilization parameter may include the performance utilization and the time utilization. In some examples, the lifespan utilization parameter may indicate a ratio between the performance utilization and the time utilization.

For example, the lifespan utilization parameter may indicate whether the memory apparatus 310 is ahead of or behind the estimated lifespan of the memory apparatus 310. As an example, if the performance utilization is greater than the time utilization, then the lifespan utilization parameter may indicate that the memory apparatus 310 is behind of the estimated lifespan of the memory apparatus 310. If the time utilization is greater than the performance utilization, then the lifespan utilization parameter may indicate that the memory apparatus 310 is ahead the estimated lifespan of the memory apparatus 310. As used herein, “behind” the estimated lifespan may refer to the performance utilization and the time utilization indicating that the memory apparatus 310 has performed more operations than expected at a current point in the estimated lifespan of the memory apparatus 310 (e.g., indicating that the memory apparatus 310 is on pace to reach the performance-based estimation of the estimated lifespan before reaching the time-based estimation of the estimated lifespan). For example, the memory apparatus 310 being behind the estimated lifespan may refer to the memory apparatus 310 aging faster than expected. As used herein, “ahead of” the estimated lifespan may refer to the performance utilization and the time utilization indicating that the memory apparatus 310 has performed fewer operations than expected at a current point in the estimated lifespan of the memory apparatus 310 (e.g., indicating that the memory apparatus 310 is on pace to reach the time-based estimation of the estimated lifespan before reaching the performance-based estimation of the estimated lifespan). For example, the memory apparatus 310 being ahead of the estimated lifespan may refer to the memory apparatus 310 aging slower than expected.

In some aspects, the lifespan utilization parameter may be a value. For example, the lifespan utilization parameter may be a ratio between the performance utilization (e.g., in a decimal form of a percentage) and the time utilization (e.g., in a decimal form of a percentage). The value may be indicative of how far ahead of or behind the memory apparatus 310 is of the estimated lifespan of the memory apparatus 310. In other aspects, the lifespan utilization parameter may be a binary representation of whether the memory apparatus 310 is ahead of or behind the estimated lifespan of the memory apparatus 310 (e.g., a binary zero (0) may indicate that the memory apparatus 310 is ahead of the estimated lifespan, and a binary one (1) may indicate that the memory apparatus 310 is behind the estimated lifespan).

In some aspects, the memory apparatus 310 may determine whether the memory apparatus has any additional operations to be performed in addition to the one or more internal maintenance operations. The additional operations may be optional maintenance operations. For example, the additional operations may not be needed to ensure suitable or acceptable performance of the memory apparatus 310, but may be configured to improve the performance of the memory apparatus 310 (e.g., the additional operations may be optional performance enhancing operations).

For example, the additional operations may include hot and cold data sorting. “Hot” data may refer to data that is frequently access and/or actively used, whereas “cold” data may refer to data that is infrequently accessed and/or infrequently used. Hot and cold data sorting may enable the memory apparatus 310 to optimize storage performance, cost-effectiveness, and/or resource utilization by aligning storage and management strategies with the access patterns and requirements of different types of data. Additionally, or alternatively, the additional operations may include data sequentialization (e.g., to correct out-of-order data). Additionally, or alternatively, the additional operations may include a wear leveling operation (e.g., static wear leveling). Additionally, or alternatively, the additional operations may include a table garbage collection operation (e.g., to perform table garbage collection, such as for one or more logical-to-physical mapping tables). Additionally, or alternatively, the additional operations may include a table sequentialization operation (e.g., to correct out-of-order physical page table records). Additionally, or alternatively, the additional operations may include a data misalignment correction (e.g., to correct any data misalignments). Additionally, or alternatively, the additional operations may include a zonification operation (e.g., to perform zonification of data in mixed-host-write data areas with zoned UFS). The types of additional operations described herein are provided as examples. The memory apparatus 310 may determine that other types of additional operations are to be performed in a similar manner as described herein.

As shown by reference number 335, the memory apparatus 310 may adjust (e.g., modify or otherwise change) the first amount of work (e.g., determined by the memory apparatus 310 as described in connection with reference number 325) to obtain a second amount of work. The second amount of work may be referred to herein as an adjusted amount of work. For example, the memory apparatus 310 may adjust the first amount of work based on one or more factors or parameters. For example, the memory apparatus 310 may adjust the first amount of work based on the one or more lifespan utilization parameters and/or one or more types of additional operations to be performed by the memory apparatus 310.

For example, if a lifespan utilization parameter indicates that the memory apparatus 310 is ahead of the estimated lifespan of the memory apparatus 310, then the memory apparatus 310 may increase the first amount of work to obtain the second amount of work. For example, if the memory apparatus 310 is ahead of the estimated lifespan of the memory apparatus, then the memory apparatus 310 may adjust the first amount of work to enable the memory apparatus 310 to perform additional work for internal maintenance because the memory apparatus 310 is currently on pace to reach the time-based estimation of the estimated lifespan before reaching the performance-based estimation of the estimated lifespan (e.g., therefore the memory apparatus 310 can perform more work for internal maintenance, thereby improving the performance of the memory apparatus 310). If the lifespan utilization parameter indicates that the memory apparatus 310 is behind the estimated lifespan of the memory apparatus 310, then the memory apparatus 310 may decrease the first amount of work to obtain the second amount of work. For example, if the memory apparatus 310 is behind the estimated lifespan of the memory apparatus, then the memory apparatus 310 may adjust the first amount of work to reduce the amount of work for internal maintenance, because the memory apparatus 310 is currently on pace to reach the performance-based estimation of the estimated lifespan before reaching the time-based estimation of the estimated lifespan (e.g., therefore the memory apparatus 310 can reduce wear of memory cells of the memory apparatus 310, thereby improving the likelihood that the memory apparatus 310 remains operational for the duration of the time-based estimation of the estimated lifespan).

In some aspects, the memory apparatus 310 may adjust the first amount of work based on a value of the lifespan utilization parameter. For example, an amount by which the first amount of work is adjusted may be based on, or otherwise associated with, the value of the lifespan utilization parameter. For example, if the value of the lifespan utilization parameter indicates that the memory apparatus 310 is further ahead of or behind the estimated lifespan, then the adjustment of the first amount of work may be larger. If the value of the lifespan utilization parameter indicates that the memory apparatus 310 is less ahead of or behind the estimated lifespan, then the adjustment of the first amount of work may be smaller.

Additionally, or alternatively, the memory apparatus 310 may adjust the first amount of work based on the one or more types of additional operations to be performed by the memory apparatus 310. In some aspects, the memory apparatus 310 may adjust the first amount of work using the one or more types of additional operations based on the lifespan utilization parameter indicating that the memory apparatus 310 is ahead of the estimated lifespan of the memory apparatus 310. For example, if the lifespan utilization parameter indicates that the memory apparatus 310 is behind the estimated lifespan of the memory apparatus 310, then the memory apparatus 310 may refrain from adjusting the first amount of work based on the one or more types of additional operations (e.g., because additional operations should be limited if the memory apparatus 310 is behind the estimated lifespan of the memory apparatus 310).

The memory apparatus 310 may increase the first amount of work to obtain the second amount of work based on the one or more types of additional operations to be performed by the memory apparatus 310. For example, the memory apparatus 310 may determine which types of additional operations are to be performed by the memory apparatus 310. The one or more types of additional operations may be associated with respective sizes or respective amounts of work. In some aspects, the memory apparatus 310 may determine a size or amount of work associated with each additional operation in a similar manner as described elsewhere herein, such as in connection with reference number 325. The memory apparatus 310 may increase the first amount of work to obtain the second amount of work based on the sizes or amounts of work associated with the one or more types of additional operations. This may enable the memory apparatus 310 to obtain additional time to perform the or more types of additional operations during a time that may have otherwise only been allocated for the memory apparatus 310 to perform the one or more internal maintenance operations. As a result, the memory apparatus 310 may optimize the utilization of allocated time for maintenance (e.g., allocated by the host system 305, as described in more detail elsewhere herein), thereby improving the performance of the memory apparatus 310.

As shown by reference number 340, the memory apparatus 310 may transmit, and the host system 305 may receive, an indication of the second amount of work. For example, the memory apparatus 310 may transmit an indication of an amount of internal maintenance operation work (e.g., the second amount of work and/or an adjusted amount of work) to be completed for the memory apparatus 310. For example, the device may transmit an indication of an adjusted amount of work that is modified from a baseline size of the internal maintenance operations, as described in more detail elsewhere herein. For example, the memory apparatus 310 may report an amount (or size) of work for internal maintenance that is based on a balance or consideration of performance and lifespan of the memory apparatus 310. The second amount of work may be a size of the amount of work (e.g., in megabytes). Additionally, or alternatively, the second amount of work may be an estimated amount of time (e.g., a duration) associated with a performance of the internal maintenance operation work by the memory apparatus 310.

For example, by the memory apparatus 310 transmitting the indication of the second amount of work, the memory apparatus 310 may communicate a tailored or optimized view of the maintenance needs of the memory apparatus 310. In some aspects, the reported amount of work takes into account the considerations of lifespan, data organization, and/or optimization goals, thus enabling a more refined maintenance schedule negotiation with the host system 305. In some aspects, the transmission of the second amount of work may be based on, or in response to, the memory apparatus 310 receiving the request from the host system 305 (e.g., the request described in connection with reference number 320).

As shown in FIG. 3C, and by reference number 345, the host system 305 may determine scheduling information for internal maintenance operations of the memory apparatus 310 based on the reported amount of work (e.g., the second amount of work). For example, the host system 305 may determine a timing and/or a duration for the memory apparatus to perform one or more internal maintenance operations while minimizing interruptions to the activities of the host system 305. In some aspects, by determining the scheduling information based on the second amount of work, the host system 305 can more efficiently plan or perform operations of the host system 305, thereby resulting in better system performance.

The host system 305 may determine the scheduling information based on the second amount of work and one or more operation parameters of the host system 305. For example, the one or more operation parameters may include a charging state (e.g., indicating whether a battery of the host system 305 is being charged), a battery level (e.g., of the battery of the host system 305), an activity level (e.g., indicating whether a user is actively performing operations via the host system 305), and/or one or more applications executing on the host system 305, among other examples. For example, the host system 305 may determine an available time period during which the memory apparatus 310 is to perform internal maintenance based on the one or more operation parameters. The host system 305 may determine the available time period based on activity or usage levels of the host system 305, a traffic pattern or usage pattern of the host system 305, a charging state or battery level of the host system 305, and/or other factors that are indicative of whether the performance of internal maintenance operations by the memory apparatus 310 will negatively impact performance of the host system 305.

The host system 305 may determine scheduling information (e.g., a starting time and a duration) for the performance of internal maintenance operations based on the available time period (e.g., to schedule the internal maintenance operations to be performed during the available time period). This may enable the host system 305 to cause the memory apparatus 310 (e.g., to schedule the memory apparatus 310) to perform the internal maintenance operations during the available time period, thereby reducing the likelihood that the performance of internal maintenance operations by the memory apparatus 310 will negatively impact performance of the host system 305.

Additionally, the host system 305 may determine the scheduling information based on the second amount of work (e.g., reported by the memory apparatus 310 as described in connection with reference number 340). For example, the host system 305 may determine a duration (e.g., an amount of time) for which the memory apparatus 310 is to perform the one or more internal maintenance operations based on the second amount of work. This may improve the likelihood that the host system 305 causes, triggers, or otherwise schedules the memory apparatus 310 to perform an amount of internal maintenance that aligns, corresponds to, or is otherwise based on with the amount of work as determined by the memory apparatus 310.

In some aspects, the host system 305 may determine that the duration (e.g., an amount of time) for which the memory apparatus 310 is to perform the one or more internal maintenance operations is not sufficient for the memory apparatus 310 to perform the second amount of work. As an example, the memory apparatus 310 may request 30 seconds to perform internal maintenance (e.g., the second amount of work may indicate that the memory apparatus 310 estimates that the performance of internal maintenance is to take 30 seconds). The host system 305 may determine that the memory apparatus can only perform internal maintenance for 10 seconds before the performance of the internal maintenance negatively impacts or degrades the performance of the host system 305. In such examples, the scheduling information may include an urgency rating. The urgency rating may indicate whether the memory apparatus 310 is to prioritize urgent or higher priority internal maintenance operations during the time resources allocated or indicated by the scheduling information. For example, the host system 305 may determine that the host system 305 is unable to grant the request of the memory apparatus 310 to perform the second amount of work, but the host system 305 may be able to enable the memory apparatus 310 to perform some of the second amount of work. The host system 305 may include the urgency rating (e.g., an indication of urgency for the internal maintenance to be performed) to indicate to the memory apparatus 310 that urgent or high priority internal maintenance operations should be performed by the memory apparatus 310.

As shown by reference number 350, the host system 305 may transmit, and the memory apparatus 310 may receive, the scheduling information. The scheduling information may be included in a command transmitted by the host system 305. The command may indicate that the memory apparatus 310 is to perform one or more internal maintenance operations in accordance with the scheduling information. For example, the command may trigger or cause the memory apparatus 310 to perform internal maintenance for an amount of time indicated by the scheduling information. The command may be a host-initiated internal maintenance command, such as an HID command, among other examples.

As shown by reference number 355, the memory apparatus 310 may determine one or more internal maintenance operations to be performed based on the scheduling information. For example, the memory apparatus 310 may determine if the amount of time indicated by the scheduling information is sufficient to perform the second amount of work. If the amount of time indicated by the scheduling information is sufficient to perform the second amount of work, then the memory apparatus 310 may determine that the operations (e.g., the one or more internal maintenance operations and/or the one or more additional operations) that were the basis for the second amount of work are to be performed.

If the amount of time indicated by the scheduling information is not sufficient to perform the second amount of work, then the memory apparatus 310 may prioritize the performance of one or more or operations. For example, if the scheduling information includes the urgency rating or indication, then the memory apparatus 310 may determine one or more internal maintenance operations to be performed based on an urgency or priority level of the one or more internal maintenance operations. In some aspects, if the amount of time indicated by the scheduling information is not sufficient to perform the second amount of work, then the memory apparatus 310 may determine that any additional operations are not to be performed.

As shown by reference number 360, the memory apparatus 310 may perform the one or more internal maintenance operations (and/or the one or more additional operations) in accordance with the scheduling information. For example, the memory apparatus 310 may perform the one or more internal maintenance operations (and/or the one or more additional operations) based on, or in response to, receiving the scheduling information (e.g., the command) from the host system 305. The memory apparatus 310 may perform the one or more internal maintenance operations (and/or the one or more additional operations) at a starting time and/or for a duration indicated by the scheduling information. The memory apparatus 310 may perform the one or more internal maintenance operations (and/or the one or more additional operations) that are determined by the memory apparatus 310, such as in connection with reference number 355.

For example, the memory apparatus 310 may execute one or more operations, such as garbage collection, data management, and/or wear-leveling, among other examples, as indicated by the scheduling information. In some aspects, by the memory apparatus 310 performing the internal maintenance operations in accordance with the scheduling information provided by the host system 305, the memory apparatus 310 can optimize internal maintenance (e.g., based on reporting the second amount of work) while accommodating the operational needs of the host system 305. Additionally, or alternatively, while performing the one or more internal maintenance operations, the memory apparatus 310 may monitor a performance and resource utilization. The memory apparatus 310 may refine future work adjustments and scheduling requests based on the performance and resource utilization. As an example, during a scheduled defragmentation operation, if the memory apparatus 310 identifies an unexpected opportunity to perform an additional data realignment that benefits subsequent read speeds within the amount of time indicated by the scheduling information, then the memory apparatus 310 may dynamically include this additional task, enabling enhanced performance of the memory apparatus 310 while remaining compliant with the host-defined schedule.

As indicated above, FIGS. 3A-3C are provided as an example. Other examples may differ from what is described with regard to FIGS. 3A-3C.

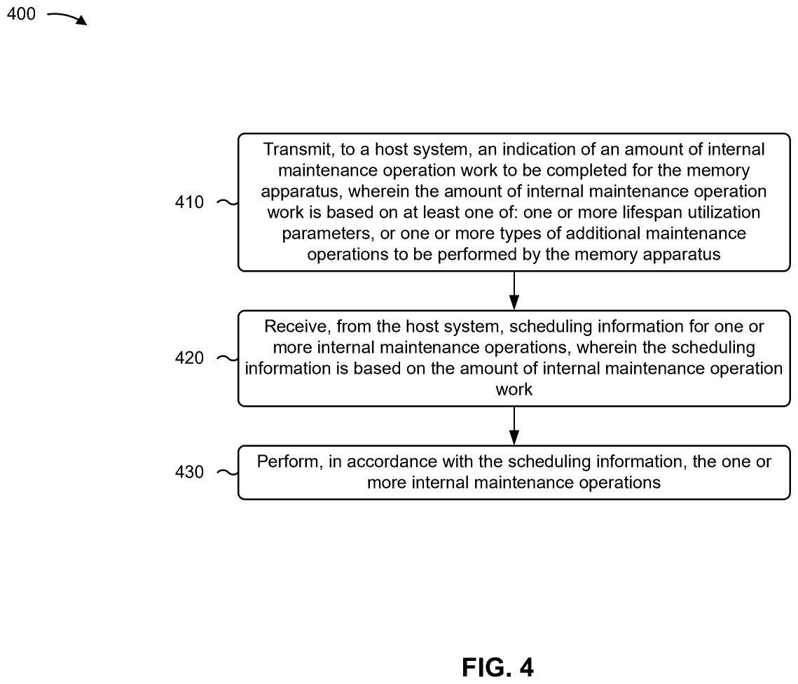

FIG. 4 is a flowchart of an example method 400 associated with reporting for host initiated internal maintenance operations. In some implementations, a memory apparatus (e.g., the memory apparatus 310, the memory system 110, and/or a memory device 120) may perform or may be configured to perform the method 400. In some implementations, another device or a group of devices separate from or including the memory apparatus (e.g., the system 100, the host system 305, the host system 105, and/or the host processor 150) may perform or may be configured to perform the method 400. Additionally, or alternatively, one or more components of the memory apparatus (e.g., the memory system controller 115, the local controller 125, the memory array 130, and/or the volatile memory array 135) may perform or may be configured to perform the method 400. Thus, means for performing the method 400 may include the memory apparatus and/or one or more components of the memory apparatus.

Additionally, or alternatively, a non-transitory computer-readable medium may store one or more instructions that, when executed by the memory apparatus, cause the memory apparatus to perform the method 400.

As shown in FIG. 4, the method 400 may include transmitting, to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus (block 410). As further shown in FIG. 4, the method 400 may include receiving, from the host system, scheduling information for one or more internal maintenance operations, wherein the scheduling information is based on the amount of internal maintenance operation work (block 420). As further shown in FIG. 4, the method 400 may include performing, in accordance with the scheduling information, the one or more internal maintenance operations (block 430).

The method 400 may include additional aspects, such as any single aspect or any combination of aspects described below and/or described in connection with one or more other methods or operations described elsewhere herein.

In a first aspect, the method 400 includes determining a first amount of work based on a size of freed memory space associated with the internal maintenance operation work to be completed for the memory apparatus, and determining a second amount of work based on the first amount of work and at least one of the one or more lifespan utilization parameters or the one or more types of additional maintenance operations, where the amount of internal maintenance operation work is based on the second amount of work.

In a second aspect, alone or in combination with the first aspect, the method 400 includes increasing the first amount of work based on the one or more lifespan utilization parameters.

In a third aspect, alone or in combination with one or more of the first and second aspects, the method 400 includes decreasing the first amount of work based on the one or more lifespan utilization parameters.

In a fourth aspect, alone or in combination with one or more of the first through third aspects, the one or more lifespan utilization parameters indicate a write endurance utilization of the memory apparatus relative to an age of the memory apparatus.

In a fifth aspect, alone or in combination with one or more of the first through fourth aspects, the age of the memory apparatus is based on a real-time clock indication or an internal clock of the memory apparatus.

In a sixth aspect, alone or in combination with one or more of the first through fifth aspects, the write endurance utilization is based on a comparison of a quantity of program-erase cycles performed by the memory apparatus to a cycle rating for the memory apparatus.

In a seventh aspect, alone or in combination with one or more of the first through sixth aspects, the one or more internal maintenance operations include at least one of a defragmentation operation, a garbage collection operation, or a folding operation.

In an eighth aspect, alone or in combination with one or more of the first through seventh aspects, the amount of internal maintenance operation work is an adjusted amount of work that is adjusted based on at least one of the one or more lifespan utilization parameters or the one or more types of additional maintenance operations.

In a ninth aspect, alone or in combination with one or more of the first through eighth aspects, the scheduling information allocates time resources during which the memory apparatus is to perform the one or more internal maintenance operations, the scheduling information includes an urgency rating, and the one or more internal maintenance operations are determined based on the urgency rating.

In a tenth aspect, alone or in combination with one or more of the first through ninth aspects, the amount of internal maintenance operation work includes at least one of a size of the internal maintenance operation work, or an estimated amount of time for completion of the internal maintenance operation work.

In an eleventh aspect, alone or in combination with one or more of the first through tenth aspects, the one or more types of additional maintenance operations include at least one of hot and cold data sorting, data sequentialization, a wear leveling operation, a table garbage collection operation, a table sequentialization operation, a data misalignment correction, or a zonification operation.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

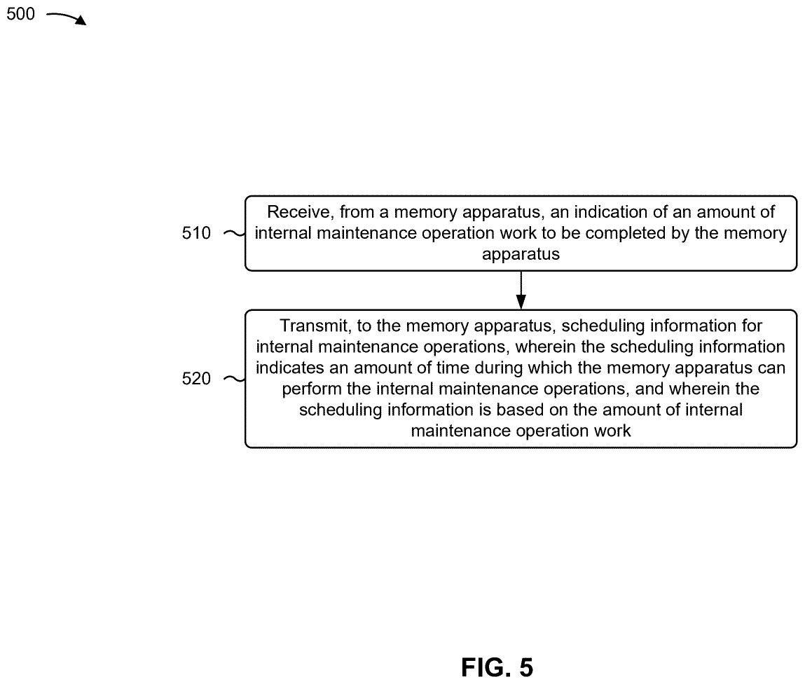

FIG. 5 is a flowchart of an example method 500 associated with reporting for host initiated internal maintenance operations. In some implementations, a host system (e.g., the host system 305 and/or the host system 105) may perform or may be configured to perform the method 500. In some implementations, another device or a group of devices separate from or including the host system (e.g., the system 100, the memory apparatus 310, the memory system 110, the memory device 120, the memory system controller 115, and/or the local controller 125) may perform or may be configured to perform the method 500. Additionally, or alternatively, one or more components of the host system (e.g., the host processor 150) may perform or may be configured to perform the method 500. Thus, means for performing the method 500 may include the host system and/or one or more components of the host system. Additionally, or alternatively, a non-transitory computer-readable medium may store one or more instructions that, when executed by the host system, cause the host system to perform the method 500.

As shown in FIG. 5, the method 500 may include receiving, from a memory apparatus, an indication of an amount of internal maintenance operation work to be completed by the memory apparatus (block 510). As further shown in FIG. 5, the method 500 may include transmitting, to the memory apparatus, scheduling information for internal maintenance operations, wherein the scheduling information indicates an amount of time during which the memory apparatus can perform the internal maintenance operations, and wherein the scheduling information is based on the amount of internal maintenance operation work (block 520).

The method 500 may include additional aspects, such as any single aspect or any combination of aspects described below and/or described in connection with one or more other methods or operations described elsewhere herein.

In a first aspect, the method 500 includes determining the scheduling information based on the amount of internal maintenance operation work and one or more operation parameters of the host system.

In a second aspect, alone or in combination with the first aspect, the one or more operation parameters include at least one of a charging state, a battery level, an activity level, or one or more applications executing on the host system.

In a third aspect, alone or in combination with one or more of the first and second aspects, the method 500 includes receiving, from the memory apparatus, an indication that the internal maintenance operations are to be performed by the memory apparatus, and transmitting, to the memory apparatus, a request for the amount of work based on receiving the indication that the internal maintenance operations are to be performed by the memory apparatus, where the indication of the amount of internal maintenance operation work is received based on transmitting the request.

In a fourth aspect, alone or in combination with one or more of the first through third aspects, the indication of the amount of internal maintenance operation work indicates a first amount of work, and the scheduling information schedules the memory apparatus to perform a second amount of work that is based on the first amount of work and one or more operation parameters of the host system.

In a fifth aspect, alone or in combination with one or more of the first through fourth aspects, the scheduling information includes an urgency rating.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

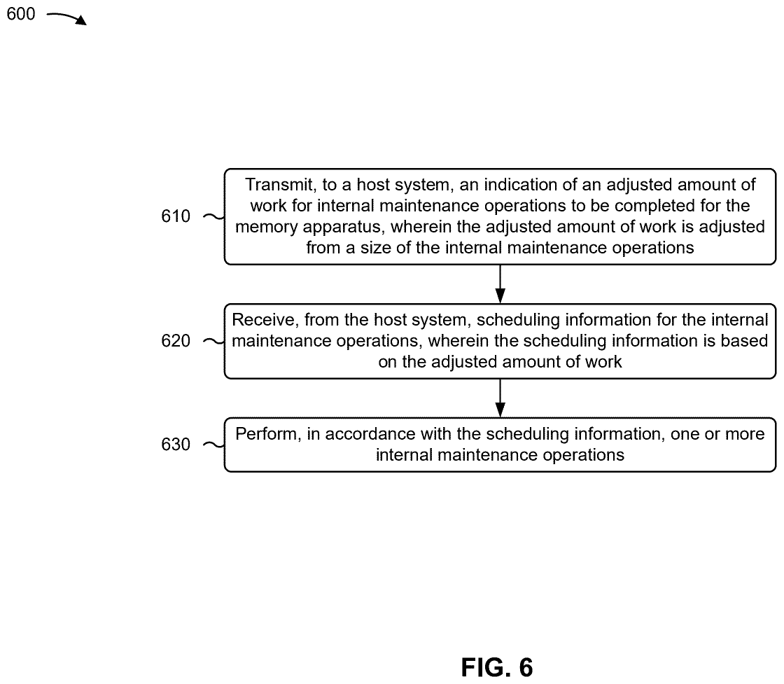

FIG. 6 is a flowchart of an example method 600 associated with reporting for host initiated internal maintenance operations. In some implementations, a memory apparatus (e.g., the memory apparatus 310, the memory system 110, and/or a memory device 120) may perform or may be configured to perform the method 600. In some implementations, another device or a group of devices separate from or including the memory apparatus (e.g., the system 100, the host system 305, the host system 105, and/or the host processor 150) may perform or may be configured to perform the method 600. Additionally, or alternatively, one or more components of the memory apparatus (e.g., the memory system controller 115, the local controller 125, the memory array 130, and/or the volatile memory array 135) may perform or may be configured to perform the method 600. Thus, means for performing the method 600 may include the memory apparatus and/or one or more components of the memory apparatus.

Additionally, or alternatively, a non-transitory computer-readable medium may store one or more instructions that, when executed by the memory apparatus, cause the memory apparatus to perform the method 600.

As shown in FIG. 6, the method 600 may include transmitting, to a host system, an indication of an adjusted amount of work for internal maintenance operations to be completed for the memory apparatus, wherein the adjusted amount of work is adjusted from a size of the internal maintenance operations (block 610). As further shown in FIG. 6, the method 600 may include receiving, from the host system, scheduling information for the internal maintenance operations, wherein the scheduling information is based on the adjusted amount of work (block 620). As further shown in FIG. 6, the method 600 may include performing, in accordance with the scheduling information, one or more internal maintenance operations (block 630).

The method 600 may include additional aspects, such as any single aspect or any combination of aspects described below and/or described in connection with one or more other methods or operations described elsewhere herein.

In a first aspect, the method 600 includes adjusting the size of the internal maintenance operations to obtain the adjusted amount of work based on at least one of one or more lifespan utilization parameters, or one or more types of the additional maintenance operations.

In a second aspect, alone or in combination with the first aspect, the one or more lifespan utilization parameters indicate whether an actual utilization of the memory apparatus is behind or ahead of an estimated lifespan of the memory apparatus, and adjusting the size of the internal maintenance operations includes adjusting the size of the internal maintenance operations based on whether the actual utilization of the memory apparatus is behind or ahead of the estimated lifespan.

In a third aspect, alone or in combination with one or more of the first and second aspects, the one or more types of additional maintenance operations include one or more optional internal maintenance operations, and adjusting the size of the internal maintenance operations includes increasing the size of the internal maintenance operations based on the one or more types of additional maintenance operations including the one or more optional internal maintenance operations.

In a fourth aspect, alone or in combination with one or more of the first through third aspects, the method 600 includes receiving, from the host system, a request for an indication of an amount of work for the internal maintenance operations, where transmitting the indication of the adjusted amount of work is based on receiving the request.

In a fifth aspect, alone or in combination with one or more of the first through fourth aspects, the indication of the adjusted amount of work indicates a size of the adjusted amount of work or an estimated amount of time associated with the memory apparatus performing the adjusted amount of work.

In a sixth aspect, alone or in combination with one or more of the first through fifth aspects, the size of the internal maintenance operations is an estimated amount of memory space generated by performing the internal maintenance operations.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory apparatus includes one or more controllers configured to: transmit, to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus; receive, from the host system, scheduling information for one or more internal maintenance operations, wherein the scheduling information is based on the amount of internal maintenance operation work; and perform, in accordance with the scheduling information, the one or more internal maintenance operations.

In some implementations, a host system includes one or more controllers configured to: receive, from a memory apparatus, an indication of an amount of internal maintenance operation work to be completed by the memory apparatus; and transmit, to the memory apparatus, scheduling information for internal maintenance operations, wherein the scheduling information indicates an amount of time during which the memory apparatus can perform the internal maintenance operations, and wherein the scheduling information is based on the amount of internal maintenance operation work.

In some implementations, a method includes transmitting, by a memory apparatus and to a host system, an indication of an adjusted amount of work for internal maintenance operations to be completed for the memory apparatus, wherein the adjusted amount of work is adjusted from a size of the internal maintenance operations; receiving, by the memory apparatus and from the host system, scheduling information for the internal maintenance operations, wherein the scheduling information is based on the adjusted amount of work; and performing, by the memory apparatus and in accordance with the scheduling information, one or more internal maintenance operations.

In some implementations, a memory apparatus includes one or more controllers configured to: transmit, to a host system, an indication of an adjusted amount of work for internal maintenance operations to be completed for the memory apparatus, wherein the adjusted amount of work is adjusted from a size of the internal maintenance operations; receive, from the host system, scheduling information for the internal maintenance operations, wherein the scheduling information is based on the adjusted amount of work; and perform, in accordance with the scheduling information, one or more internal maintenance operations.

In some implementations, a method includes transmitting, by a memory apparatus and to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus; receiving, by the memory apparatus and from the host system, scheduling information for one or more internal maintenance operations, wherein the scheduling information is based on the amount of internal maintenance operation work; and performing, by the memory apparatus, the one or more internal maintenance operations in accordance with the scheduling information.

In some implementations, a method includes receiving, by a host system and from a memory apparatus, an indication of an amount of internal maintenance operation work to be completed by the memory apparatus; and transmitting, by the host system and to the memory apparatus, scheduling information for internal maintenance operations, wherein the scheduling information indicates an amount of time during which the memory apparatus can perform the internal maintenance operations, and wherein the scheduling information is based on the amount of internal maintenance operation work.

In some implementations, an apparatus includes means for transmitting, to a host system, an indication of an adjusted amount of work for internal maintenance operations to be completed for the memory apparatus, wherein the adjusted amount of work is adjusted from a size of the internal maintenance operations; means for receiving, from the host system, scheduling information for the internal maintenance operations, wherein the scheduling information is based on the adjusted amount of work; and means for performing, in accordance with the scheduling information, one or more internal maintenance operations.

In some implementations, an apparatus includes means for transmitting, to a host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus; means for receiving, from the host system, scheduling information for one or more internal maintenance operations, wherein the scheduling information is based on the amount of internal maintenance operation work; and means for performing the one or more internal maintenance operations in accordance with the scheduling information.

In some implementations, an apparatus includes means for receiving, from a memory apparatus, an indication of an amount of internal maintenance operation work to be completed by the memory apparatus; and means for transmitting, to the memory apparatus, scheduling information for internal maintenance operations, wherein the scheduling information indicates an amount of time during which the memory apparatus can perform the internal maintenance operations, and wherein the scheduling information is based on the amount of internal maintenance operation work.

In some implementations, a system includes a host system; a memory apparatus; and one or more components configured to: communicate, from the memory apparatus to the host system, an indication of an amount of internal maintenance operation work to be completed for the memory apparatus, wherein the amount of internal maintenance operation work is based on at least one of: one or more lifespan utilization parameters, or one or more types of additional maintenance operations to be performed by the memory apparatus; communicate, from the host system to the memory apparatus, scheduling information for one or more internal maintenance operations, wherein the scheduling information is based on the amount of internal maintenance operation work; and perform, via the memory apparatus, the one or more internal maintenance operations in accordance with the scheduling information.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory apparatus, comprising:
one or more controllers configured to:
transmit, to a host system, an indication of an amount of internal maintenance operation work to be completed for the memory apparatus,
wherein the amount of internal maintenance operation work is based on at least one of:
one or more lifespan utilization parameters, or
one or more types of additional maintenance operations to be performed by the memory apparatus;
receive, from the host system, scheduling information for one or more internal maintenance operations,
wherein the scheduling information is based on the amount of internal maintenance operation work; and
perform, in accordance with the scheduling information, the one or more internal maintenance operations.

2. The memory apparatus of claim 1, wherein the one or more controllers are further configured to:
determine a first amount of work based on a size of freed memory space associated with the internal maintenance operation work to be completed for the memory apparatus; and
determine a second amount of work based on the first amount of work and at least one of the one or more lifespan utilization parameters or the one or more types of additional maintenance operations,
wherein the amount of internal maintenance operation work is based on the second amount of work.

3. The memory apparatus of claim 2, wherein the one or more lifespan utilization parameters indicate that an actual utilization of the memory apparatus is ahead of estimated lifespan of the memory apparatus, and wherein the one or more controllers, to determine the second amount of work, are configured to:
increase the first amount of work based on the one or more lifespan utilization parameters.

4. The memory apparatus of claim 2, wherein the one or more lifespan utilization parameters indicate that an actual utilization of the memory apparatus is behind an estimated lifespan of the memory apparatus, and wherein the one or more controllers, to determine the second amount of work, are configured to:
decrease the first amount of work based on the one or more lifespan utilization parameters.

5. The memory apparatus of claim 1, wherein the one or more lifespan utilization parameters indicate a write endurance utilization of the memory apparatus relative to an age of the memory apparatus.

6. The memory apparatus of claim 5, wherein the age of the memory apparatus is based on a real-time clock indication or an internal clock of the memory apparatus.

7. The memory apparatus of claim 5, wherein the write endurance utilization is based on a comparison of a quantity of program-erase cycles performed by the memory apparatus to a cycle rating for the memory apparatus.

8. The memory apparatus of claim 1, wherein the one or more internal maintenance operations include at least one of:
a defragmentation operation,
a garbage collection operation, or
a folding operation.

9. The memory apparatus of claim 1, wherein the amount of internal maintenance operation work is an adjusted amount of work that is adjusted based on at least one of the one or more lifespan utilization parameters or the one or more types of additional maintenance operations.

10. The memory apparatus of claim 1, wherein the scheduling information allocates time resources during which the memory apparatus is to perform the one or more internal maintenance operations,
wherein the scheduling information includes an urgency rating, and
wherein the one or more internal maintenance operations are determined based on the urgency rating.

11. The memory apparatus of claim 1, wherein the amount of internal maintenance operation work includes at least one of:
a size of the internal maintenance operation work, or
an estimated amount of time for completion of the internal maintenance operation work.

12. The memory apparatus of claim 1, wherein the one or more types of additional maintenance operations include at least one of:
hot and cold data sorting,
data sequentialization,
a wear leveling operation,
a table garbage collection operation,
a table sequentialization operation,
a data misalignment correction, or
a zonification operation.

13. A host system, comprising:
one or more controllers configured to:
receive, from a memory apparatus, an indication of an amount of internal maintenance operation work to be completed by the memory apparatus; and
transmit, to the memory apparatus, scheduling information for internal maintenance operations,
wherein the scheduling information indicates an amount of time during which the memory apparatus can perform the internal maintenance operations, and
wherein the scheduling information is based on the amount of internal maintenance operation work.

14. The host system of claim 13, wherein the one or more controllers are further configured to:
determine the scheduling information based on the amount of internal maintenance operation work and one or more operation parameters of the host system.

15. The host system of claim 14, wherein the one or more operation parameters include at least one of:
a charging state,
a battery level,
an activity level, or
one or more applications executing on the host system.

16. The host system of claim 13, wherein the one or more controllers are further configured to:
receive, from the memory apparatus, an indication that the internal maintenance operations are to be performed by the memory apparatus; and
transmit, to the memory apparatus, a request for the amount of work based on receiving the indication that the internal maintenance operations are to be performed by the memory apparatus,
wherein the indication of the amount of internal maintenance operation work is received based on transmitting the request.

17. The host system of claim 13, wherein the indication of the amount of internal maintenance operation work indicates a first amount of work, and
wherein the scheduling information schedules the memory apparatus to perform a second amount of work that is based on the first amount of work and one or more operation parameters of the host system.

18. The host system of claim 13, wherein the scheduling information includes an urgency rating.

19. A method, comprising:
transmitting, by a memory apparatus and to a host system, an indication of an adjusted amount of work for internal maintenance operations to be completed for the memory apparatus,
wherein the adjusted amount of work is adjusted from a size of the internal maintenance operations;
receiving, by the memory apparatus and from the host system, scheduling information for the internal maintenance operations,
wherein the scheduling information is based on the adjusted amount of work; and
performing, by the memory apparatus and in accordance with the scheduling information, one or more internal maintenance operations.

20. The method of claim 19, further comprising:
adjusting the size of the internal maintenance operations to obtain the adjusted amount of work based on at least one of:
one or more lifespan utilization parameters, or
one or more types of additional maintenance operations.

21. The method of claim 20, wherein the one or more lifespan utilization parameters indicate whether an actual utilization of the memory apparatus is behind or ahead of an estimated lifespan of the memory apparatus, and wherein adjusting the size of the internal maintenance operations comprises:
adjusting the size of the internal maintenance operations based on whether the actual utilization of the memory apparatus is behind or ahead of the estimated lifespan.

22. The method of claim 20, wherein the one or more types of additional maintenance operations include one or more optional internal maintenance operations, and wherein adjusting the size of the internal maintenance operations comprises:
increasing the size of the internal maintenance operations based on the one or more types of additional maintenance operations including the one or more optional internal maintenance operations.

23. The method of claim 19, further comprising:
receiving, from the host system, a request for an indication of an amount of work for the internal maintenance operations,
wherein transmitting the indication of the adjusted amount of work is based on receiving the request.

24. The method of claim 19, wherein the indication of the adjusted amount of work indicates a size of the adjusted amount of work or an estimated amount of time associated with the memory apparatus performing the adjusted amount of work.

25. The method of claim 19, wherein the size of the internal maintenance operations is an estimated amount of memory space generated by performing the internal maintenance operations.
